(19) United States
(12) Patent Application Publication
(10) Pub. No.: US 2003/0179033 A1
(43) Pub. Date: Sep. 25, 2003

(54) Control of a power load

(76) Inventors: Philippe Bienvenu, Allauch (FR); Antoine Pavlin, Puyricard (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/393,048

(22) Filed: Mar. 20, 2003

(30) Foreign Application Priority Data
Mar. 22, 2002 (FR) 02/03624

(51) Int. Cl. H03K 17/687

(52) U.S. Cl. 327/427

(57) ABSTRACT

A load supply control circuit comprising an integrated switch and its control circuit within a same package, and circuitry for controlling the level of the current flowing through the switch according to a difference in instantaneous temperature between the switch and its environment.

### BACKGROUND OF THE INVENTION

1. Field of the Invention

The present invention generally relates to the control of the power supply of a power load (the operating power of which ranges between a few Watts and some hundred Watts). The present invention more specifically relates to the control of a power switch intended to supply a load. It may be, for example, in the automobile industry, headlights, defrosting devices, motors such as those intended to control windows or wipers, etc. In this case, the switch is generally controlled in switched mode (in all or nothing). According to another example of application, the switch is controlled in linear mode, for example, to control the voltage provided to a load.

2. Discussion of the Related Art

FIG. 1 partially illustrates, in the form of functional blocks, a conventional example of a circuit 2 (CONTROL) for controlling a power load (Q) 1. Circuit 2 is series-connected with load 1, between two respectively high and low or ground supply lines Vcc and GND. Control circuit 2 essentially includes a power switch 3, interposed between high supply line Vcc and an output terminal OUT of circuit 2. Terminal OUT is intended to be connected to a first supply terminal of load 1, another terminal of load 1 being at ground GND. An inverse configuration (load connected between line Vcc and terminal OUT of circuit 2) is also possible. Switch 3 is then grounded. Switch 3 is a controllable switch, typically a MOS transistor, associated with a drive circuit (DRIV) 4. Circuit 4 provides a signal for controlling switch 3.

As applied to a control in linear mode, circuit 4 is used to regulate, across load 1, a desired nominal voltage. For this purpose, circuit 4 compares current voltage Vout on output terminal OUT of control circuit 2 with a reference value Vref.

As applied to a switched-mode control, the connections (illustrated in dotted lines in FIG. 1) of circuit 4 to voltage Vref and to output terminal OUT are omitted. Circuit 4 however receives a reference signal (not shown) for turning on or off load 1. This reference is generally also present for a linear mode control.

A control circuit such as illustrated in FIG. 1 comprises two types of protections of switch 3.

A first protection is a current protection to limit the current flowing through switch 3 and/or trough the wiring external to circuit 2, to a value tolerable in case of a short-circuit, that is, for the case where load 1 finds itself in short-circuit, potentially generating a current that can destroy switch 3 and/or the external wiring. For this purpose, a current limiter (LIM) 5 is placed between the control terminal of switch 3 and output terminal OUT, and is active when the current through switch 3 exceeds a predetermined threshold Imax.

A second protection is a heat protection to limit the heating of power switch 3. For this purpose, drive circuit 4 comprises a comparator of the current temperature (in practice, a voltage representative of temperature) of switch 3 with respect to a predetermined threshold Tⱼ^{th}. Current temperature Tj of switch 3 is given by a sensor (not shown) provided in the switch. When the switch overheats, circuit 4 modifies its control. Either it turns off the switch (switching), or it reduces its control reference point (linear state).

The efficiency of the above protections depends on the thermal capacity of the circuit (more specifically, of the package-chip assembly), that is, on its capacity of carrying off heat. Indeed, the lower the circuit's thermal capacity, the lower the maximum current that can flow through switch 3. Either the current operating limit, that is, the threshold of limiter 5, is lowered to avoid overheating, or the heat protection of circuit 4 comes more often into operation. In both cases, this adversely affects the operation of load 1.

Moreover, the setting of current and temperature thresholds Imax and Tⱼ^{th} must fulfil aims that may be contradictory. In particular, the current limitation must be chosen to be as small as possible to limit the temperature rise of the switch in case of a short-circuit in the load. But too low a current limiting threshold Imax may adversely affect the load starting. Indeed, upon starting, the surge current of the load may be such that it exceeds threshold Imax. In such a case, the load starting time is lengthened, under a current remaining greater than a nominal current. This generates a heating for a longer time. Even if this heating does not trigger the heat protection because threshold Tⱼ^{th} has been provided accordingly to avoid adversely affecting the starting, an accelerated wearing of the circuit occurs due to the heat constraints that it undergoes. In practice, connection wires are torn, the rear surface of the chip integrating switch 3 detaches, and/or defects occur in the single-crystal structure of the semiconductor, typically silicon, in which switch 3 is integrated. These defects may further appear after a relatively long operating time, which makes them difficult to detect upon qualification tests of the component and of the application using it.

If current limitation threshold Imax is provided not to be reached upon starting of load 1, large-amplitude heat variations then occur in case of a short-circuit.

In some loads (for example, vehicle indicators), periodic lightings with idle times, the short duration of which do not allow sufficient cooling down of the circuit, must be allowed. To enable proper operation, a high heat threshold must then be set. There again, this shortens the circuit lifetime. It could be envisaged to lower the heat threshold. However, this would then prevent any “hot” starting of a load 1. A sufficient cooling down of switch 3 would then indeed have to be awaited to restart the load. This would even prevent, in the case of a linear state control, a restarting at lower power.

The above disadvantages are all the more critical as the power dissipation capacity of the circuit is small. Currently, with continued miniaturization of integrated circuits, there is an inevitable decrease in the heat capacity of circuits, and thus a faster heat rise.

### SUMMARY OF THE INVENTION

The present invention aims at providing a load control circuit which overcomes the disadvantages of known circuits.

The present invention more specifically aims at providing a control circuit ensuring an efficient heat protection without adversely affecting the operation of loads in nominal state.

The present invention also aims at enabling use of a current limitation threshold which is greater than the load surge current, without adversely affecting the protection against short-circuits.

The present invention also aims at providing a solution which eliminates accelerated component aging problems.

The present invention further aims at providing a circuit compatible with the miniaturization and the decrease in thermal capacity that it generates.

To achieve these and other objects, the present invention provides a load supply control circuit, said circuit comprising an integrated switch and its control circuit within a same package, and means for controlling the level of the current flowing through said switch according to a difference in instantaneous temperature between the switch and its environment.

According to an embodiment of the present invention, said temperature difference is measured by means of a first sensor integrated to the switch and of a second sensor integrated in its control circuit.

According to an embodiment of the present invention, the switch and its control circuit are integrated on the same semiconductor chip.

According to an embodiment of the present invention, said means are formed of a comparator receiving signals representative of temperatures of the switch and of its environment.

According to an embodiment of the present invention, a drive circuit capable of providing a control signal to the switch is provided with heat protection means modifying the control reference point of the switch when the temperature thereof exceeds a temperature threshold, said means modifying the value of said temperature threshold according to said temperature difference.

According to an embodiment of the present invention, the circuit comprises a limiter of the current in the switch with respect to a limitation threshold, said means modifying the value of said limitation threshold according to said temperature difference.

According to an embodiment of the present invention, the control is linear.

According to an embodiment of the present invention, the control is in all or nothing.

According to an embodiment of the present invention, said switch is attached on the same frame as the rest of said circuit, said means being capable of comparing the temperature of said switch and the temperature of said frame close to the rest of the control circuit.

The foregoing objects, features and advantages of the present invention will be discussed in detail in the following non-limiting description of specific embodiments in connection with the accompanying drawings.

### BRIEF DESCRIPTION OF THE DRAWINGS

FIG. 1, previously described, partially and schematically shows a power load associated with a known control circuit;

FIG. 2 schematically illustrates the temperature variation in a power switch upon variation of the power of a load controlled by this switch; and

FIG. 3 partially and schematically shows a control circuit according to an embodiment of the present invention.

### DETAILED DESCRIPTION

The present invention originates from a novel analysis of the temperature behavior of a power switch such as a MOS transistor and of the circuit integrating it.

FIG. 2 is a timing diagram which schematically illustrates the variation along time t of the temperatures within a chip integrating the control circuit of a load, at the level of power switch Tⱼ and at the level of its close environment such as the package, the temperature of which is close to that T_{F} of the chip frame.

The load starting time is considered as the origin (0) of time t. It is also considered that originally, the system is stable from a certain time and that the initial temperatures of the junction Tⱼ⁰ and of the frame T_{F}⁰ are equal.

Upon power variation across the load, before stabilization at the nominal operation, the frame temperature T_{F} varies according to a bell-shaped curve, to reach a value T_{F}¹ slightly greater than initial value T_{F}⁰.

Upon the same power variation, temperature Tⱼ of the power switch varies in a much stronger way still according to a bell-shaped curve. The maximum transient value Tⱼ^{max} reached by the switch is much greater than the maximum transient value T_{F}^{max} reached by its environment. Once the desired nominal state has been reached, temperature Tⱼ¹ of the switch remains generally greater than that T_{F}¹ reached by its environment (nominal difference ΔTnom).

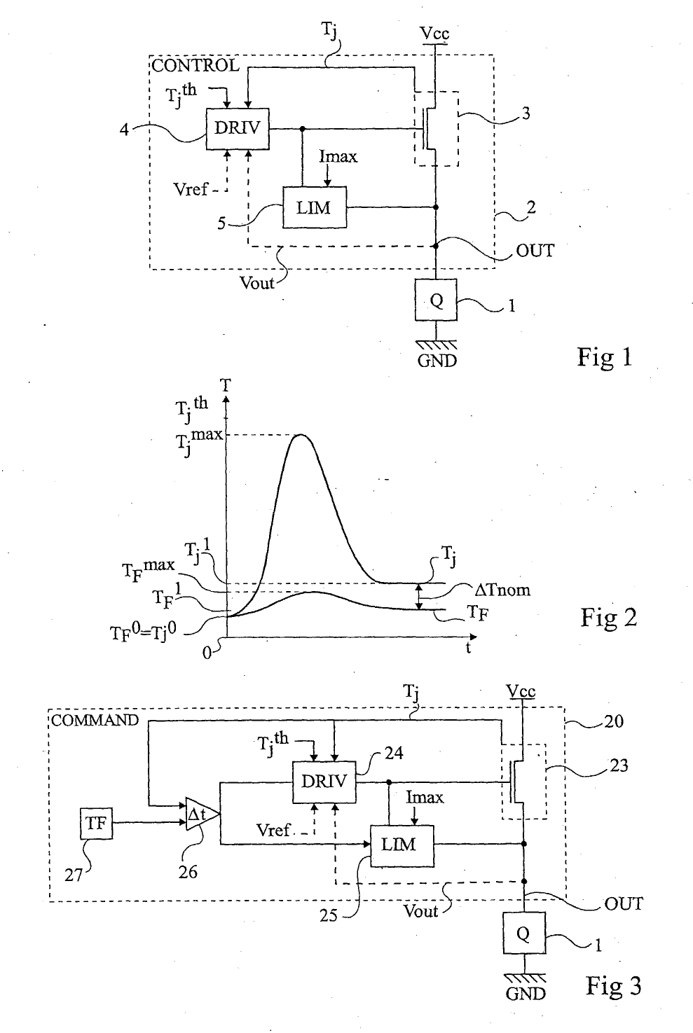

The operation described hereabove assumes both that the current limitation threshold (Imax, FIG. 1) is greater than the surge current of the load and that heat protection threshold Tⱼ^{th} is greater than maximum temperature Tⱼ^{max} reached in the transient state.

The present inventors consider that the power switch lifetime problems previously indicated appear from as soon as the temperature difference between the MOS transistor and its close environment, that is, temperature difference ΔT between the source junction of the transistor and its package, exceeds a given value which depends on the sole characteristics of the power switch, and this, even if the absolute temperature Tⱼ of the junction remains smaller than heat circuit breaking threshold temperature Tⱼ^{th}.

It should be noted that the accelerated wearing due to abrupt variations of the switch temperature is independent from the nominal operating temperature thereof. Thus, a power switch may exhibit a large temperature operating range (for example, from −40° C. to +150° C.) and exhibit, within this range, malfunctions in case of abrupt temperature variations (for example, corresponding to a variation on the order of 100° C. of the junction temperature in a few milliseconds).

FIG. 3 partially shows in the form of functional blocks a control circuit (COMMAND) 20 according to an embodiment of the present invention. Circuit 20 is, in the example shown, interposed between a high supply line Vcc and a first terminal of a power load 1 (Q), another terminal of which is connected to a voltage reference or ground line GND. Circuit 20 comprises, in series between high power supply Vcc and an output terminal OUT, a power switch 23, for example, a MOS transistor, controlled by a driver circuit (DRIV) 24. Circuit 24 provides a control signal to the gate of transistor 23.

Switch 23 may be controlled in switched mode or in linear mode. In this latter case, circuit 24 receives a voltage reference Vref and output voltage Vout (connection in dotted lines).

Conventionally, circuit 24 is also capable of modifying its control, that is, of turning off switch 23 or decreasing its reference point to decrease the current, if its internal temperature Tⱼ exceeds a predetermined threshold Tⱼ^{th}.

Control circuit 20 also comprises a current limiter (LIM) 25, connected between output terminal OUT and the control line of switch 23. Conventionally, limiter 25 aims at limiting the gate-source potential difference of transistor 23, and thus the current, for protection against short-circuits. However, according to the present invention, limiting current Imax is set to a value greater than the maximum value of the surge current of the load upon starting (or at an operating mode change).

According to the present invention, circuit 20 also comprises a circuit 26 (ΔT) for controlling the temperature difference, capable of evaluating the instantaneous temperature difference ΔT between transistor 23 and its close environment. The latter actually includes the package temperature, assimilated to that T_{F} of the frame on which the integrated circuit chip comprising control circuit 20 is arranged. A temperature (T_{F}) sensor 27 is provided in a portion of the chip integrating control circuit 20 (preferably, in the actual control circuit), preferably chosen to be as far away as possible from switch 23. As a specific example, temperature sensor 27 is a PN junction (for example, a diode, a bipolar transistor, etc.), the conduction threshold of which varies according to temperature. On the side of switch 23, the temperature is also measured, conventionally, by using one of the transistor junctions.

The present invention more specifically applies to the case where control circuit 20 and power switch 23 are integrated in a same circuit, and will be described hereafter in relation with this application. However, it more generally applies as soon as the control circuit and the switch, even on separate chips, are in a same package or supported by a same frame.

Circuit 26 is, for example, a comparator receiving, as an input, signals representative of the temperatures of switch Tⱼ and of its environment T_{F}. The output signal of circuit 26 is provided to circuit 24 and to limiter 25. As an alternative, a single one of circuits 24 and 25 receives the output signal of circuit 26.

According to a preferred embodiment, circuit 26 provides an (analog) output signal ΔT dynamically modifying the temperature threshold of the heat protection of circuit 24 and/or the activation threshold of current limiter 25. This modification however only occurs from a threshold ΔTref chosen to be greater than the maximum acceptable nominal difference ΔTnom (FIG. 2) and, preferably, greater than the difference at the load starting.

According to another embodiment, circuit 26 provides a (digital) output signal which will exhibit a first state as long as the current value of the temperature difference ΔT is smaller than a maximum value ΔTmax. The output signal takes a second state, different from the first one, as soon as the current value of temperature difference ΔT reaches maximum value ΔTmax. The output signal of circuit 26 returns to the first state as soon as current value ΔT becomes once again equal to or smaller than a reference value ΔTref (chosen, for example, like for the preferred embodiment) smaller than maximum value ΔTmax. Circuit 26 is, for example, a hysteresis comparator. Current I is then, as long as the temperature difference remains greater than ΔTref, chopped in switch 23.

An advantage of the temperature difference control in the vicinity of switch 23 performed by the present invention is that this avoids malfunctions of known circuits.

In particular, prejudicial compromises in the sizing of current threshold Imax and absolute temperature threshold Tⱼ^{th} are avoided.

Especially, the present invention enables making the selection of value Imax of the current limitation independent from heating risks of a specific power switch, and a function only of the breakdown current characteristics of the connection leads between the different terminals, to concentrate on the protection against short-circuits. The present invention thus enables setting a limiting current Imax greater than in the case of known circuits.

Due to this, the control circuit of the present invention does not lengthen the starting time of a load by allowing a threshold Imax of protection against short-circuits which is greater than the normal surge current. However, in case of an abrupt increase in the current linked to a short-circuit, the fast heating which occurs causes the starting of the circuit of protection against temperature intervals of the present invention, which effectively limits the current in the switch.

Another advantage of the present invention is that it enables hot startings. Indeed, the absolute temperature threshold Tⱼ^{th} is now set to a greater value as compared to the value chosen by compromise in the conventional case. Accordingly, as long as the starting is compatible with difference threshold ΔTref, absolute temperature threshold Tⱼ^{th}, and current threshold Imax, the load can start while hot.

The modifications brought according to the present invention are only located in the logic portion of the control circuit. Indeed, the power switch is not modified with respect to a known circuit. The gain in operating reliability of the switch widely compensates for the semiconductor surface area necessary to integrate the different previously-described functions.

Of course, the present invention is likely to have various alterations, modifications, and improvements which will readily occur to those skilled in the art.

In particular, the practical forming of the different components of a control circuit according to the present invention is within the abilities of those skilled in the art based on the functional indications given hereabove. Similarly, the present invention applies to a configuration where the load is directly connected to high supply line Vcc as well as to the shown configuration, where it is grounded.

Further, the determining of thresholds ΔTmax, ΔTref, Imax, and Tⱼ^{th} depends on the application and is also within the abilities of those skilled in the art. For example, in the case of a power switch of MOS transistor type, reference value ΔTref will range between 30 and 100° C.

Further, any other temperature difference configuration may be envisaged. For example, the initial temperatures of the switch and of its package may be different from each other and their final temperatures could be equal. The final temperature of one or the other of the two elements—package and switch—may be equal to its initial temperature.

Finally, the power switch may be of any type, for example, a bipolar transistor, a thyristor, or a triac.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A load supply control circuit, said circuit comprising an integrated switch and its control circuit in a same package, comprising means for controlling the level of the current flowing through said switch as a function of a difference in instantaneous temperature between the switch and its environment.

2. The circuit of claim 1, wherein said temperature difference is measured by a first sensor integrated to the switch and a second sensor integrated in its control circuit.

3. The circuit of claim 1, wherein the switch and its control circuit are integrated on a same semiconductor chip.

4. The circuit of claim 1, wherein said controlling means comprise a comparator receiving signals representative of temperatures of the switch and of its environment.

5. The circuit of claim 1, comprising a drive circuit capable of providing a control signal to the switch, said driver circuit being provided with heat protection means modifying the control reference point of the switch when the temperature thereof exceeds a temperature threshold, wherein said means modify the value of said temperature threshold according to said temperature difference.

6. The circuit of claim 1, comprising a limiter of the current in the switch with respect to a limitation threshold, wherein said means modify the value of said limitation threshold according to said temperature difference.

7. The circuit of claim 1, wherein the control is linear.

8. The circuit of claim 1, wherein the control is in all or nothing.

9. The circuit of claim 1, wherein said switch is attached on a same frame as said circuit, and wherein said means are capable of comparing the temperature of said switch and the temperature of said frame close to the control circuit.
